(19) United States
(12) Patent Application Publication
(10) Pub. No.: US 2003/0170948 A1
(43) Pub. Date: Sep. 11, 2003

(54) Method and apparatus for slicing semiconductor wafers

(75) Inventors: Milind S. Bhagavat, St. Louis, MO (US); Dale A. Witte, O'Fallon, MO (US); Steven L. Kimbel, St. Charles, MO (US); David A. Sager, Hazelwood, MO (US); John W. Peyton, St. Charles, MO (US)

Correspondence Address: SENNIGER POWERS LEAVITT AND ROEDEL, ONE METROPOLITAN SQUARE, 16TH FLOOR, ST LOUIS, MO, 63102, US

(73) Assignee: MEMC Electronic Materials, Inc.

(21) Appl. No.: 10/377,271

(22) Filed: Feb. 28, 2003

Related U.S. Application Data
(60) Provisional application No. 60/362,379, filed on Mar. 7, 2002.

(51) Int. Cl. H01L 21/8238

(52) U.S. Cl. 438/200

(57) ABSTRACT

An apparatus for slicing semiconductor wafers from a single-crystal ingot includes a web of wire for slicing the ingot into wafers and a frame having a head for supporting the ingot during slicing. The apparatus further includes a controller and a temperature sensor disposed in the head and operable to send a signal to the controller indicating head temperature. The controller is operable to control temperature of a fluid directed to the head in response to the signal thereby to control the head temperature. Methods of slicing wafers are also disclosed.

### CROSS-REFERENCE TO RELATED APPLICATIONS

This application claims priority from U.S. Provisional Application Serial No. 60/362,379 filed Mar. 7, 2002, which is incorporated herein by reference.

### BACKGROUND OF THE INVENTION

The present invention relates generally to semiconductor wafers, and more particularly to methods for slicing semiconductor wafers from single-crystal ingots.

Semiconductor wafers are generally prepared from a single crystal ingot, such as a silicon ingot. The ingot is sliced into individual wafers which are each subjected to a number of processing operations (e.g., lapping, etching and polishing) to remove damage caused by the slicing operation and to create a relatively smooth finished wafer having uniform thickness and a finished front surface. Preferably, the finished wafer is flat and featureless so that it has little or no measurable deviation or waviness in its surface topography. Waviness and the characterization and measurement thereof is more fully described in co-assigned U.S. patent application Ser. No. 10/092,479 entitled METHOD OF ESTIMATING POST-POLISHING WAVINESS CHARACTERISTICS OF A SEMICONDUCTOR WAFER, which is incorporated herein by reference. Briefly, waviness describes features in the surface topography that are measurable in a medium wavelength. Waviness is suitably measured in an as-cut (unfinished and unprocessed) wafer in its free state (i.e., not clamped or adhered to another surface), and is the deviation of a measured surface midway between the front surface and the back surface from a reference median surface. A linear profile (or section view) of the measured surface taken on a line parallel to the cutting direction is subjected to a filter (e.g., a Gaussian filter) to remove features that are not in a medium wavelength (e.g., about 50-80 mm). Note that undesirable features having a shorter wavelength (about 0.1 to 10 mm) are characterized as “roughness” (and are typically removed by downstream processes) and features having a longer wavelength (about 90 to 200 mm) are characterized as warp/bow.

The slicing operation is typically performed by an inner diameter slicing apparatus or by a wiresaw slicing apparatus SA shown in FIG. 1. Currently, most wafers are sliced by a wiresaw slicing apparatus. Generally, the wiresaw slicing apparatus SA comprises four wire guides WG around which a wire web WW is coiled. The wire guides rotate to cause the segments of the wire web to move along their lengths (axially). The ends of the wire web also move lengthwise (as indicated by the arrows) and are suitably wound on spindles (not shown). To slice the ingot IG into wafers, an abrasive slurry is sprayed onto the moving wire web and the ingot IG is forced against the web.

The wiresaw slicing apparatus has become the machine of choice for producing relatively flat semiconductor wafers. However, recently developed measuring machines, e.g., the ADE CR83 which can measure “nanotopography” features (undesirable features measurable on a nanometer scale), more precisely measure the wafer surface and reveal the extent of waviness caused by wiresaw slicing. More precise measurement of the finished wafer shows that defects such as waviness caused by slicing are often not removed in later processing operations. Semiconductor wafer customers now demand finished wafers according to stringent specifications for flatness and waviness. Accordingly, a better apparatus and method for slicing is required.

### SUMMARY OF THE INVENTION

Among the several objects of the present invention may be noted the provision of an apparatus and method for slicing semiconductor wafers which produces wafers having improved flatness and nanotopography; the provision of such an apparatus and method which inhibits waviness in the wafers; and the provision of such an apparatus and method which improves the yield of acceptable wafers.

In one aspect, the present invention is directed to an apparatus for slicing semiconductor wafers from a single-crystal ingot comprising a web of wire for slicing the ingot into wafers and a frame including a head for supporting the ingot during slicing. The apparatus further comprises a controller and a temperature sensor disposed in the head and operable to send a signal to the controller indicating head temperature. The controller is operable to control temperature of a fluid directed to the head in response to the signal thereby to control the head temperature.

In another aspect, the apparatus comprises the web of wire for slicing the ingot into wafers, the frame including the head for supporting the ingot during slicing, and temperature control means adapted for precise temperature control of the head to inhibit waviness in the wafers.

In yet another aspect, the present invention is directed to a method of slicing semiconductor wafers from a single-crystal ingot using a wafer slicing apparatus. The method comprises monitoring the temperature of at least one component of the apparatus and initiating slicing of the wafer from the ingot when the temperature is substantially steady at a predetermined temperature so as to inhibit waviness in the wafers.

In still another aspect, the present invention is directed to a method of slicing semiconductor wafers comprising heating at least one component of the apparatus and initiating slicing of the wafer from the ingot when the temperature of the component is approximately equal to a predetermined temperature so as to inhibit waviness in the wafers.

In still another aspect, a method of slicing semiconductor wafers comprises identifying a component of the apparatus in which variations in temperature thereof during slicing promote waviness in the wafer. The temperature of the component is controlled during slicing to inhibit waviness in the wafers.

Other objects and features of the present invention will be in part apparent and in part pointed out hereinafter.

### BRIEF DESCRIPTION OF THE DRAWINGS

FIG. 1 is a diagrammatic perspective view of a portion of a prior art wiresaw slicing apparatus;

FIG. 2 is a perspective view of a slicing apparatus of an embodiment of this invention;

FIG. 3 is a fragmentary sectional view taken in the plane of line 3-3 of FIG. 2;

FIG. 4 is a schematic view of a recirculating fluid loop;

FIG. 5 is a flowchart of a warm-up routine for the slicing apparatus;

FIG. 6A is a graph of filtered wafer waviness showing the results of temperature variations of a first test;

FIG. 6B is a graph of filtered temperature data for fluid flowing through a frame;

FIG. 6C is a graph of filtered temperature data for fluid flowing through a wire guide;

FIG. 7A is a composite graph of fluid temperature in contact with a head of the apparatus and the head temperature of a second test;

FIG. 7B is a composite graph of fluid temperature in contact with the frame and the frame temperature;

FIG. 7C is a composite graph of wafer waviness and temperature variation;

FIG. 7D is a composite graph of wafer waviness and temperature variation of an additional test;

FIG. 8 is a graph of wafer waviness in a wafer sliced according to this invention;

FIG. 9 is a graph of wafer waviness in a conventionally sliced wafer;

FIG. 10 is an image of a wafer conventionally sliced; and

FIG. 11 is an image of a wafer sliced according to this invention.

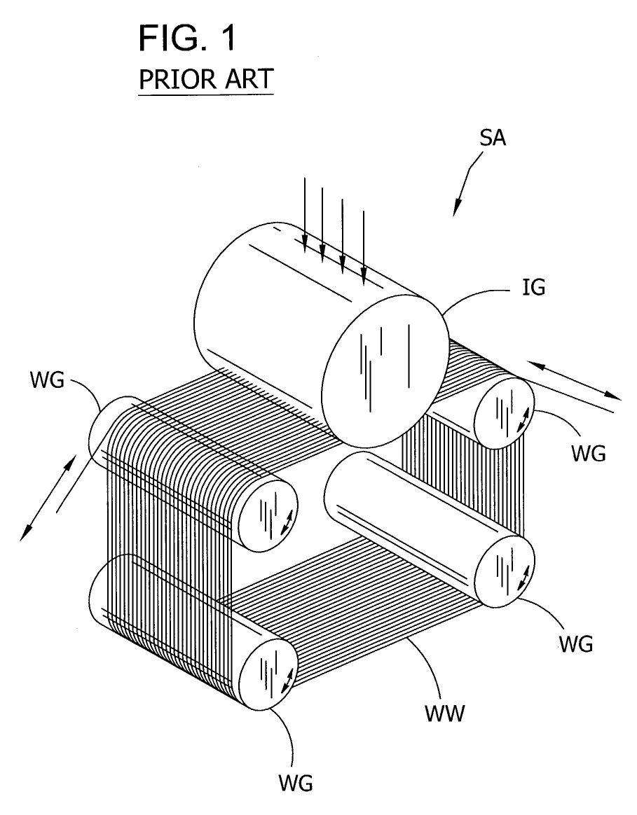

Corresponding reference characters indicate corresponding parts throughout the several views of the drawings.

### DETAILED DESCRIPTION OF THE PREFERRED EMBODIMENT

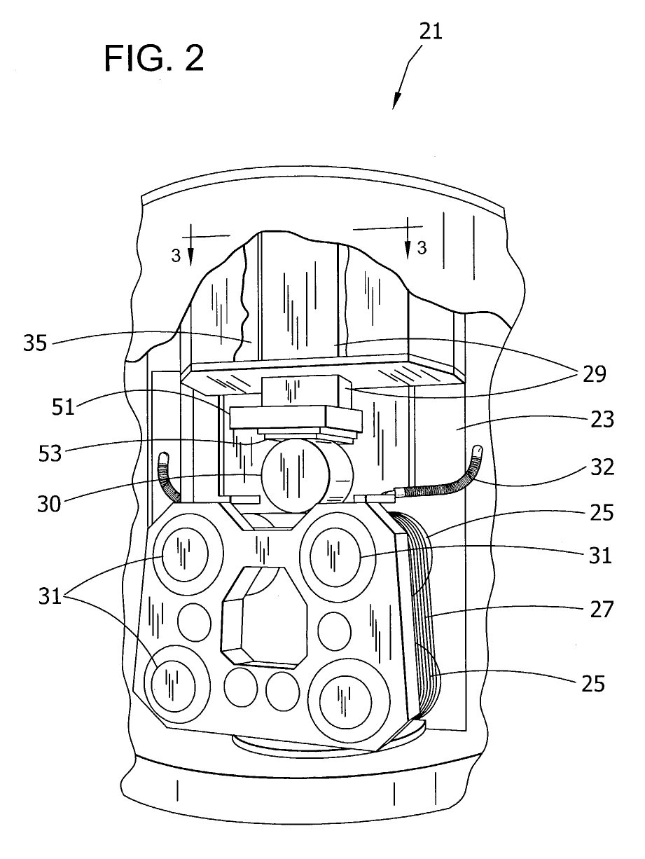

Referring now to the drawings and in particular to FIG. 2, a wiresaw slicing apparatus is designated in its entirety by the reference numeral 21. The wiresaw slicing apparatus 21 described herein is a modified Model 300E12-H made by HCT Shaping Systems of Cheseaux, Switzerland, though other models and types are contemplated. The apparatus generally comprises a frame 23 which mounts four wire guides 25 (two are partially shown) for supporting a wire web 27. The frame also mounts a movable slide or head 29 which mounts an ingot 30 for movement relative to the frame for forcing an ingot 30 into the web.

Briefly, the wire guides 25 are generally cylindrical and have a number of peripheral grooves (not shown) that receive respective wire segments making up the wire web 27 and are spaced at precise intervals. The spacing between the grooves determines the spacing between wire segments and thereby determines the thickness of the sliced wafers. The wire guides 25 rotate on bearings 31 for moving the wire segments lengthwise or axially. A cutting slurry is directed onto the wire web 27 by conduits 32.

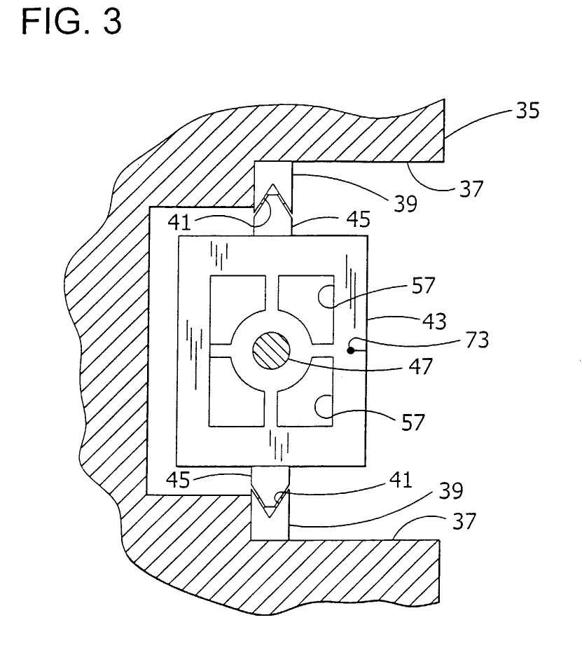

Referring to FIGS. 2 and 3, upper portion 35 of the frame is generally U-shaped in horizontal section (FIG. 3) including two inwardly-facing walls 37. Two elongate vertical rails 39 are mounted on the inwardly facing walls such that V-shaped grooves 41 in the rails face inward toward one another. A top portion 43 of the head includes two elongate V-shaped slide elements 45 mounted on opposite sides of the head to extend downward from near the top of the head. Roller bearings are suitably mounted within the grooves 41 and the slide elements 45 are positioned for slidably engaging the bearings of the rails. The head is thereby movable vertically relative to the frame. A motor-driven ball screw shaft 47 extends downward centrally through the head and a nut (not shown) is suitably connected to the head (e.g., at the upper end of the head) for moving the head vertically. Note that there is a weighted counterbalance (not shown) connected to the head to reduce the weight borne by the ball screw. A table 51 and ingot holder 53 are mounted on the lower end of the head. The ingot 30 is adhered to the ingot holder 53 by adhesive or secured by other suitable means. The head 29 includes four internal channels 57 extending longitudinally for receiving recirculating fluid. The frame also includes channels (not shown) for receiving the recirculating fluid.

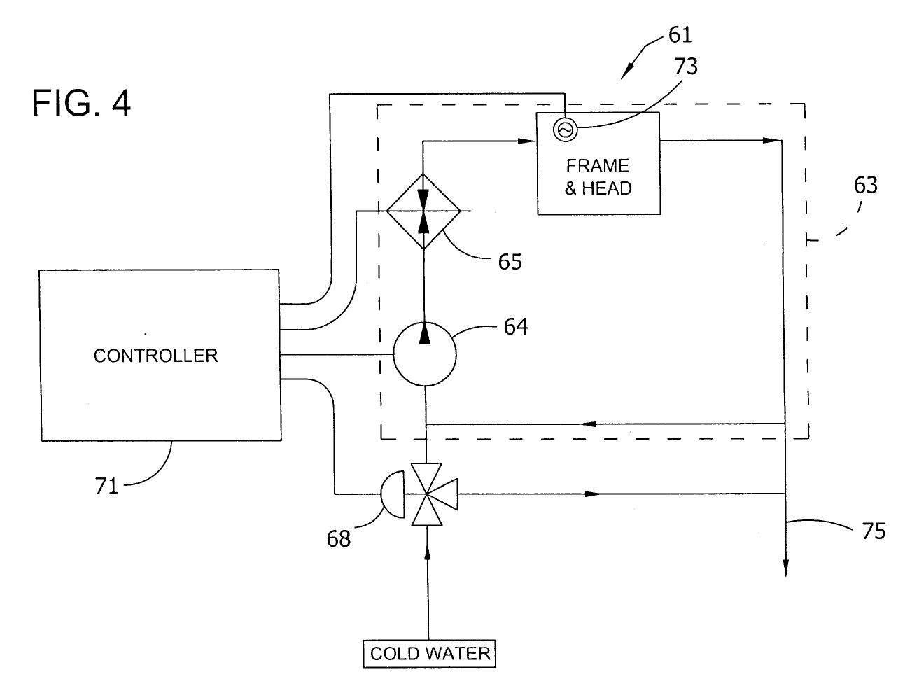

Referring to FIG. 4, a temperature control system 61 for precisely controlling the temperature of the head 29 of the frame at a set point temperature comprises a loop 63 of passages for circulating fluid (e.g., water) through a pump 64, a heater 65, and the frame 23 and head 29. Cooling fluid (e.g., cold water) may be added to the fluid in the loop by actuating a 3-way valve 68 (at the lower left of FIG. 4). The system includes a controller 71 operable to receive temperature data from a temperature sensor 73 and to control operation of the heater and the 3-way valve 68. In this embodiment, the controller receives and records signals from the temperature sensor 73 indicating temperature in the head. If the temperature of the head 29 is greater than the set point, the controller actuates the valve 68 to cause cold water to flow to the head. If the temperature of the head 29 is less than the set point, the 3-way valve 68 is controlled to direct the cold water away from the head to an outlet 75 and the controller activates the heater 65 to heat the circulating water. If the temperature is at the set point, the valve 68 is controlled to cause the cold water to flow to the outlet 75 (rather than into the loop) and the heater is turned off. Note that the apparatus 21 also includes separate temperature control systems (not shown) for controlling the temperature of fluid flowing through the wire guides 25, through the bearings 31 and for controlling the temperature of the slurry. It is contemplated that these systems may be modified to control the temperature of the wire guides and bearings, rather than the fluid.

In the present embodiment, the temperature sensor 73 is preferably embedded in the head 29 to measure the head temperature rather than the fluid in contact with the head. (The method of determining the location of the sensor is described below). The sensor 73 is preferably embedded in the steel body of the head and spaced from the inner and outer surfaces (i.e., the exposed surfaces) of the head such that it measures the temperature of the body of the head. It is contemplated that if temperature of another apparatus component, such as the frame 23, was found to be critical to inhibiting waviness (as described below), a sensor could be embedded in such component for precise temperature control thereof. In this embodiment, the temperature sensor 73 is positioned, as shown in FIG. 3, away from the channels of the head 29 and away from the outer periphery of the head so that it measures the temperature of the head and not the fluid or air temperature. The sensor 73 is positioned about 5 cm (about 2 inches) from the top of the head 29, generally in the head upper portion (i.e., the portion above the midpoint of the head and preferably above the lower ends of the slide elements 45) and in this embodiment is positioned above the slide elements. It is contemplated that other locations on the head may be found to be optimal and the sensor positioned accordingly. The sensor used in this embodiment is a thermistor, but may be a thermocouple or other temperature sensor. The sensor 73 sends a signal to the controller 71 to indicate the temperature of the head 29.

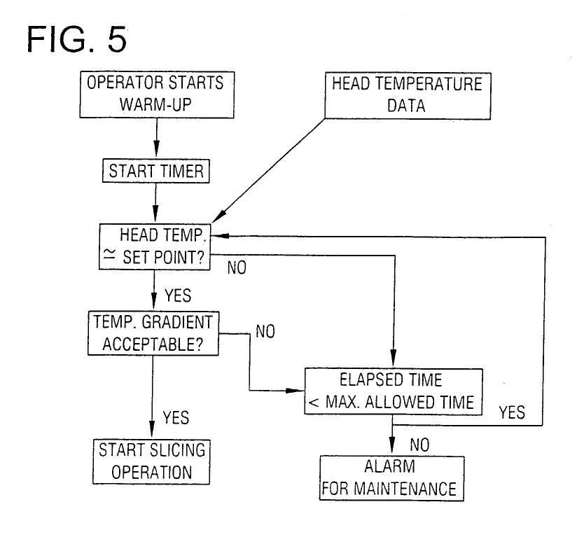

Between slicing operations, the head temperature is likely to cool to substantially less than the set point temperature. (Note that the set point temperature is typically established by the apparatus manufacturer and is broadly described as an equilibrium temperature achieved during slicing.) It is important that the head temperature be approximately equal to the set point temperature prior to initiating slicing so that during slicing the head temperature is substantially constant. Referring to FIG. 5, the controller 71 ensures that the head temperature is warmed (by heating the water as described above) to substantially the set point temperature and is substantially stable (i.e., the temperature gradient is sufficiently low) when slicing is initiated. The temperature sensor 73 signals temperature data to the controller continuously, e.g., about once per minute, and the controller stores the data. An operator presses a button which signals the controller to initiate a warm-up cycle (which includes starting wire motion) and the controller starts a timer. The controller compares the most recently recorded head temperature to the set point temperature and determines whether the head temperature is substantially equal to the set point, i.e., if the temperature is within the range discussed below, e.g., 30°±0.1° C. If the head temperature is substantially equal to the set point, the controller determines if the head temperature gradient is acceptable, i.e., if the change over the last several recorded temperatures is acceptable. Preferably, the gradient is less than or equal to about 0.3° C./min, more preferably less than or equal to about 0.2° C./min, even more preferably less than or equal to about 0.1° C./min. If the temperature gradient is acceptable, the slicing operation is initiated. If either of the measurements is not within the range, then the controller compares the time elapsed since warm-up was started with the maximum allowed time to complete warm-up. If the elapsed time exceeds the maximum allowed time, there is likely a problem in the apparatus. Accordingly, an alarm is triggered by the controller to alert the operator that maintenance of the apparatus is needed. The maximum allowed time is suitably 3 hours for the HCT apparatus described above, but the time may vary with the apparatus. If the time does not exceed the maximum allowed time, then the process is repeated upon a new temperature signal being recorded by the controller (about once per minute).

Head temperature is also precisely controlled during the slicing operation. If the head temperature is less than the set point temperature, the controller activates the heater to heat the fluid. If the head temperature is greater than the set point temperature, the controller turns off the heater and actuates the 3-way valve to cause cooling water to enter the frame and head. Preferably, the controller controls the head temperature to within about ±0.2° C., more preferably about ±0.1° C., even more preferably about ±0.05° C., and still more preferably about ±0.03° C. It is to be noted that prior art control systems control the temperature of the cooling fluid in contact with the frame, rather than the temperature of the frame itself. As such, the prior art systems control the temperature of the frame only to within about ±0.5° to about ±5° C. The system of this invention, including the temperature sensor 73 positioned in the head, provides more precise control of the head temperature because variations in the head temperature are shown below to cause waviness in the sliced wafer.

Method of Determining Temperature Control Location

Generally, a component of the slicing apparatus, or more desirably a particular location on the component, is found whereat temperature variations from the set point during slicing substantially correlate to waviness in the surface of the wafers. In other words, the method determines the component, and preferably a location on the component, whereat temperature variations are to be precisely controlled to inhibit waviness in the sliced wafers. In this embodiment, testing is performed on the HCT apparatus, modified as described below.

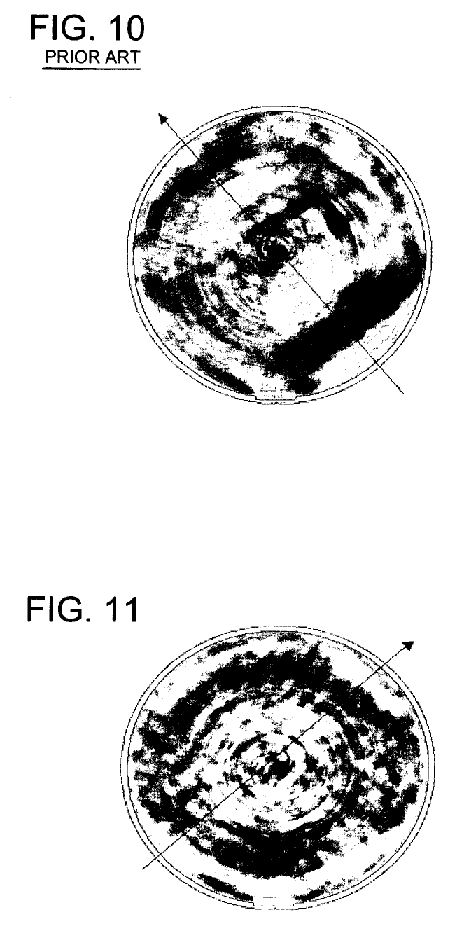

In order to determine the proper component amongst the frame (including the head), wire guides, slurry and the bearings, temperatures of the fluids in contact with the components were intentionally varied during slicing of test wafers in a first test. The temperatures of the fluids in contact with the components were varied in substantially the same manner during slicing. For example, fluid temperature was held steady at about 29° C., quickly increased to about 31° C., held steady again and then quickly decreased to about 28.5° C. The pattern was repeated with the temperature increasing to about 31.5°, decreasing to about 28° and increasing to about 31° C. In this first test, the temperature of fluid in contact with each component was varied simultaneously. In other tests, e.g., a second test described below, the temperature of fluid in contact with one or two components was varied while the temperature of fluid in contact with other components was held constant. Waviness in one of the test wafers in a free state was measured using an ADE CR83 machine. Waviness was measured along the line of slicing through the wafer (the line of slicing is shown, e.g., in FIGS. 10 and 11). The waviness data from the machine is suitably filtered using a 50-80 mm bandwidth Gaussian filter, as more fully described in co-assigned U.S. patent application Ser. No. 10/092,479. Briefly, the filter used the following weighting functions (in Fourier Domain):

F(λ)=exp(−0.6932(λ_{c}/λ)²), corresponding to the high-pass filter, and

F(λ)=1−exp(−0.6932(λ_{c}/λ)²), corresponding to the low-pass filter;

where λ_{c} represents the desired wavelength cutoff for each filter, respectively, and the coefficients −0.6932 in both equations represent a cutoff at one standard deviation from the mean. Moreover, the phase-conserving Gaussian band-pass filter uses a cutoff of about 50 millimeters (about 2.0 inches) for the high-pass filter and a cutoff of about 80 millimeters (about 3.1 inches) for the low-pass filter.

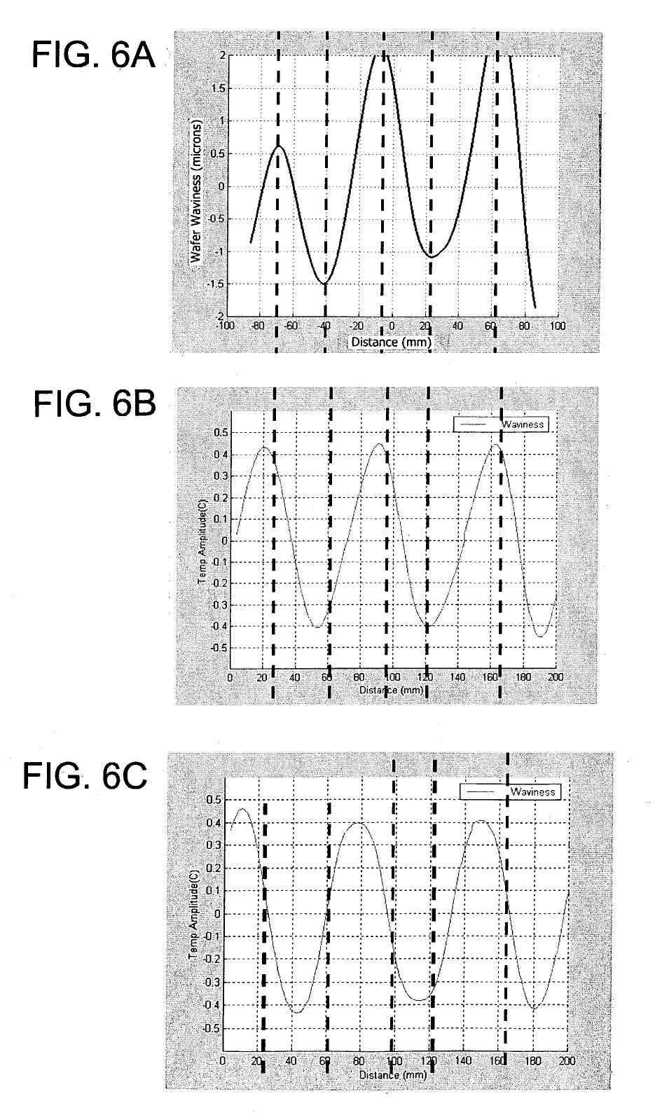

The resulting filtered waviness amplitude data for one of the sliced wafers is shown in graphical form in FIG. 6A. The graph plots the amplitude of the filtered waviness data (microns) versus the location on the wafer (in mm). Vertical dashed lines in the graph denote zero points in slope in the waviness amplitude curve. FIGS. 6B and 6C plot the filtered amplitude of variations from the set point temperature for the fluid flowing in the frame and wire guides, respectively, versus the location of the wire web relative to the wafer when the temperature variations occurred during slicing of the wafer. FIGS. 6B and 6C include the vertical dashed lines at approximately the same positions shown in FIG. 6A. (Note that the different distance scale (−100 to 100, rather than 0 to 200) of FIG. 6A is not pertinent to this analysis.) As can be seen from FIG. 6B, there is a close correlation between zero points (peaks and valleys) in the slope of the frame temperature amplitude variation curve and the vertical dashed lines. In other words, there is a close correlation between frame temperature and waviness. In contrast, FIG. 6C shows that there is substantially no correlation between zero points in the wire guide temperature amplitude variation curve and the vertical dashed lines. Likewise, graphs (not shown) of slurry and bearing temperature variation showed no significant correlation with waviness amplitude. Thus, variations in frame temperature are found to most directly correlate with waviness found in the sliced test wafer. Accordingly, the location to be controlled is in the frame.

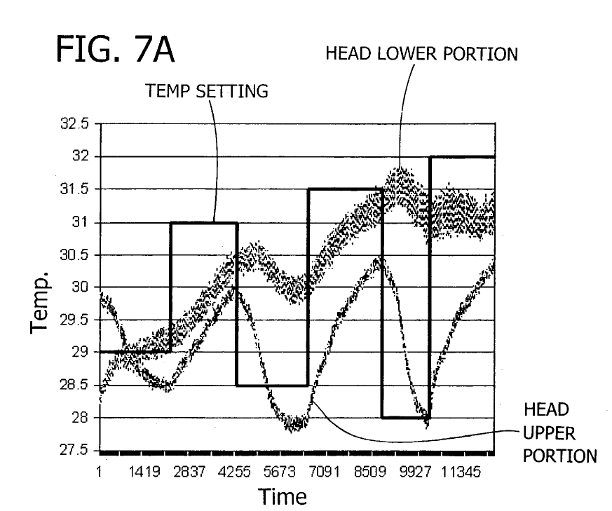

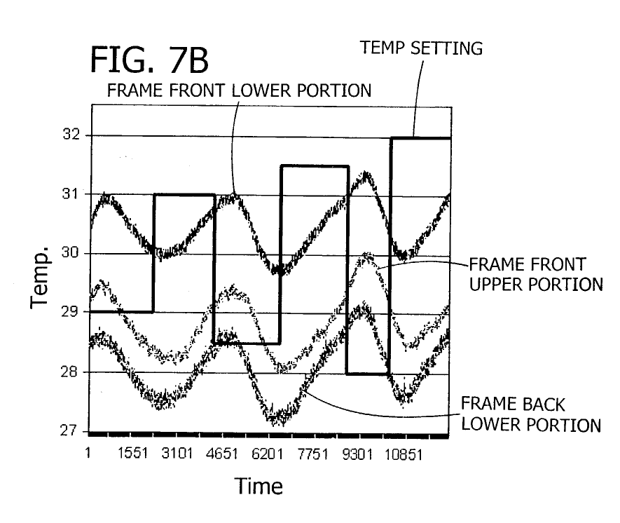

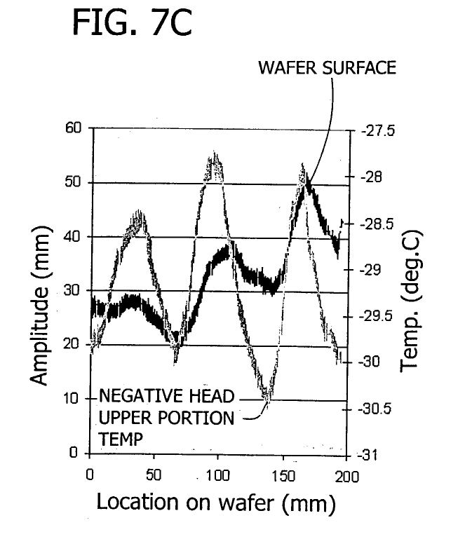

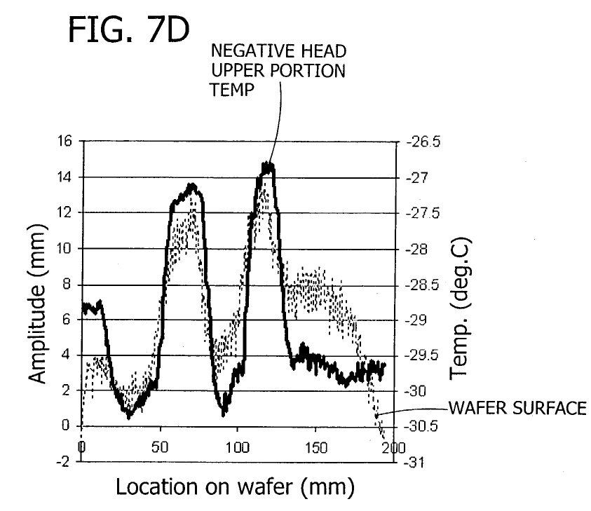

In order to pinpoint the location within the frame, in a second step or test of this method, temperature sensors (such as sensor 73 in FIG. 3) are embedded in the frame in several locations. In this test, the sensors were placed at the upper and lower portions of the head, at the upper portion of the frame in the front and the back, and at the lower portion of the frame in the front and back. Also, the fluid loop shown in FIG. 4 was modified so that there were separate cooling loops for the head and the frame and so that the temperature of fluid in contact with the head was controlled separately from the fluid in contact with the remainder of the frame. Referring to FIGS. 7A and 7B, the temperature of the fluids of both cooling loops was intentionally fluctuated during this test in a manner similar to that described above (note that the fluid temperatures are somewhat different than in the first test, as shown). Among the several locations of the frame and head at which temperature was measured, the correlation between head fluid temperature changes and the measured head upper portion temperature was significantly better than at any other measured location. In other words, there is a more significant lag between a change in the fluid temperature and a resulting change in the temperature of the frame locations and the head lower portion, as compared to a change in the temperature of the head upper portion.

The correlation between waviness and temperature changes in the head upper portion are shown graphically in FIG. 7C. The amplitude of variations from the set point temperature (temperature scale on right vertical line of FIG. 7C) in the head upper portion is shown versus the position of the wire on the wafer during slicing. Waviness amplitude data versus wire position for a sliced test wafer (taken from the center of the ingot) is also shown in FIG. 7C (amplitude scale on left vertical line). As can be seen, the waviness amplitude closely correlates with temperature variation of the head upper portion. An additional test was run wherein only the head temperature was varied. FIG. 7D shows waviness amplitude data versus wire position for a sliced test wafer of this additional test, and the test further confirms that waviness amplitude closely correlates with temperature variation of the head upper portion. Because the location of strongest correlation between temperature variation and waviness is at the head upper portion, the controller described above desirably controls the temperature of the fluid in contact with the head based on the sensor at the upper portion of the head. In other words, the temperature at the head upper portion is held substantially constant as described above.

Without being held to a particular theory, it is believed that controlling the head upper portion temperature is important to controlling waviness because the head, especially the lower portion of the head, tends to warp due to relatively small temperature changes at the head upper portion. Note that the head 29 is supported only by the rails 39 at its upper portion. Applicants have found that as low as a 0.2° C. temperature change at the head upper portion may cause significant movement of the lower portion of the head. Because such movement tends to be transverse to the lengthwise extent (the axis) of the wires forming the wire web and because such movement causes motion of the ingot transverse to the wire web, the resulting sliced wafer has significant waviness therein. Such waviness is seen in the image of FIG. 10 of the as-sliced wafer surface. The image was generated using the ADE CR83 machine. The line through the image represents the direction of slicing. Slicing began at the lower right of the wafer. A wide dark area at the lower right of the wafer denotes significant waviness. The position of the waviness shows that it occurred shortly after initiation of the slicing process and is likely due to a failure to heat the head to the set point temperature prior to initiation of slicing. In contrast, the wafer of FIG. 11 was sliced according to the method of this invention. No significant waviness can be seen therein.

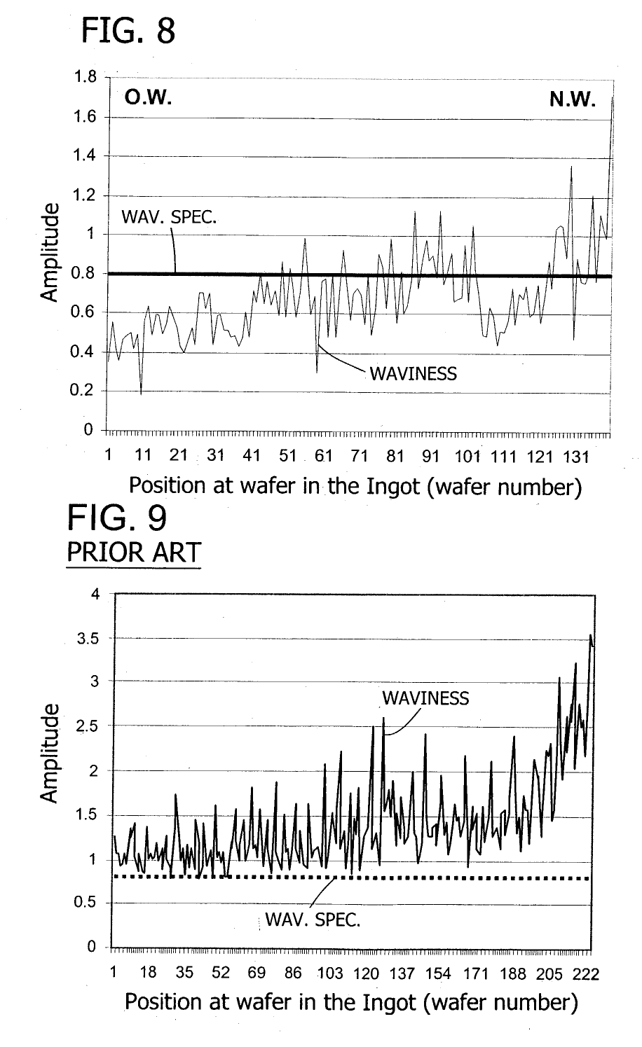

Waviness in the surface topography of an as-cut (unprocessed) wafer which is free (not adhered to another surface) should be within a predetermined specification. The amplitude of waviness features in any 160 mm span of the filtered linear profile is preferably less than 1 micron, more preferably less than 0.8 microns, even more preferably less than 0.5 microns and still more preferably less than 0.2 microns. A preferred specification of this example is as follows: the amplitude of waviness features in any 160 mm span of the filtered linear profile is less than 0.8 microns. Waviness data for substantially all wafers sliced from an ingot according to the invention is plotted in the graph of FIG. 8. The amplitude of waviness for most wafers sliced from the ingot is less than 0.8 microns. In contrast, FIG. 9 is a graph of waviness data for all wafers sliced from an ingot by a conventional method. FIG. 9 shows the amplitude of waviness for substantially all the wafers conventionally sliced is more than 0.8 microns. Accordingly, the yield of acceptable wafers is improved by the method and apparatus of this invention.

In view of the above, it will be seen that the several objects of the invention are achieved and other advantageous results attained.

When introducing elements of the present invention or the preferred embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above constructions without departing from the scope of the invention, it is intended that all matter contained in the above description or shown in the accompanying drawings shall be interpreted as illustrative and not in a limiting sense.

What is claimed is:

1. An apparatus for slicing semiconductor wafers from a single-crystal ingot comprising:
a web of wire for slicing the ingot into wafers,
a frame including a head for supporting the ingot during slicing,
a controller, and
a temperature sensor disposed in the head and operable to send a signal to the controller indicating head temperature,
the controller being operable to control temperature of a fluid directed to the head in response to the signal to thereby control the head temperature.

2. An apparatus as set forth in claim 1 further comprising a heater for heating the fluid directed to the head, the controller operable to control operation of the heater.

3. An apparatus as set forth in claim 2 further comprising a valve for directing cooling fluid to the head, the controller operable to control operation the valve.

4. An apparatus as set forth in claim 1 wherein the controller is operable to prevent initiation of slicing in response to the signal.

5. An apparatus as set forth in claim 1 wherein the controller is operable to control the head temperature to within about ±0.2° C. of a set point temperature.

6. An apparatus as set forth in claim 1 wherein the controller is operable to control the head temperature to within about ±0.1° C. of a set point temperature.

7. An apparatus as set forth in claim 1 wherein the controller is operable to control the head temperature to within about ±0.05° C. of a set point temperature.

8. An apparatus as set forth in claim 1 wherein the frame further includes rails, and the temperature sensor is located in an upper portion of the head, the upper portion being in slidable engagement with the rails.

9. An apparatus for slicing semiconductor wafers from a single-crystal ingot comprising:
a web of wire for slicing the ingot into wafers,
a frame including a head for supporting the ingot during slicing, and
temperature control means for precise temperature control of the head to inhibit waviness in the wafers.

10. An apparatus as set forth in claim 9 wherein the temperature control means includes a temperature sensor in an upper portion of the head and a controller, the sensor being operable to send a signal to the controller indicating head temperature, the controller being operable to control temperature of a fluid in contact with the head in response to the signal.

11. A method of slicing semiconductor wafers from a single-crystal ingot using a wafer slicing apparatus, the method comprising:
monitoring the temperature of at least one component of the apparatus, and
initiating slicing of the wafer from the ingot when the temperature of said component is substantially steady at a predetermined temperature so as to inhibit waviness in the wafers.

12. A method as set forth in claim 11 wherein the monitoring step includes monitoring the temperature of a movable head of the apparatus.

13. A method as set forth in claim 11 further comprising calculating a temperature gradient of the component and wherein slicing is initiated when the temperature is substantially steady such that the temperature gradient is less than or equal to about 0.3° C./min.

14. A method as set forth in claim 13 wherein slicing is initiated when the temperature is substantially steady such that the temperature gradient is less than or equal to about 0.2° C./min.

15. A method as set forth in claim 14 wherein slicing is initiated when the temperature is substantially steady such that the temperature gradient is less than or equal to about 0.1° C./min.

16. A method as set forth in claim 11 wherein initiation of slicing of a subsequent ingot is inhibited when the temperature is not substantially steady at the predetermined temperature.

17. A method as set forth in claim 16 wherein an alarm is triggered when the temperature is not substantially steady at the predetermined temperature after a maximum allowed time.

18. A method of slicing semiconductor wafers from a single-crystal ingot using a wafer slicing apparatus, the method comprising:
heating at least one component of the apparatus, and
initiating slicing of the wafer from the ingot when the temperature of said at least one component is approximately equal to a predetermined temperature so as to inhibit waviness in the wafers.

19. A method as set forth in claim 18 wherein the heating step includes heating the temperature of a movable head of the apparatus.

20. A method of slicing semiconductor wafers from at least one single-crystal ingot using a wafer slicing apparatus, the method comprising:
identifying a component of the apparatus in which variations in temperature thereof during slicing promote waviness in the wafer, and
controlling the temperature of the component during slicing to inhibit waviness in the wafers.

21. A method as set forth in claim 20 wherein the step of identifying a component includes intentionally varying the temperature of fluids in contact with selected components of the apparatus, the selected components including a frame, a head of the frame, wire guides and bearings.
